(19) United States
(12) Patent Application Publication
(10) Pub. No.: US 2006/0221585 A1
(43) Pub. Date: Oct. 5, 2006

(54) Apparatus and method for reducing noise coupling

(76) Inventor: Colin E. Brench, Stow, MA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/098,951

(22) Filed: Apr. 5, 2005

(51) Int. Cl. H05K 7/06

(52) U.S. Cl. 361/780; 361/782

(57) ABSTRACT

Method and structure for modifying the boundary conditions between edges of adjacent or nearby split power planes in a circuit layout. The modified boundary conditions reduce coupling between the power planes, which reduces noise coupling between the power planes and allows for closer spacing between the power planes. In one embodiment the modified boundary conditions include a high impedance adjacent a low impedance.

### BACKGROUND

Electronic systems, such as computers for example,. use circuit layouts having any number of electrical components or devices mounted thereon. The circuit components use power distributed by one or more power/return plane pairs associated with the circuit layout. Each power distribution arrangement includes a power plane conductor or rail and a return plane conductor or rail. Some circuit layouts are realized in the form of circuit boards which may be single layer or multilayer.

Various circuit designs may be sensitive to noise. Examples of noise include power surges, electrostatic discharge (ESD), switching noise, and coupling that can occur across boundaries between signal lines, power distribution rails and so on. In many cases, separate or “split” multiple power distribution arrangements may be provided for a single circuit board. Some of the circuits on the board are powered by a first power distribution arrangement and other circuits may be powered by one or more additional power distribution arrangements associated with the same circuit board. The use of separate power distributions allows noise sensitive circuits, for example, phase locked loop circuits, video amplifiers and so on, to be isolated from other circuits on the circuit board.

Individual power distributions may include a suppression capacitor. The suppression capacitor is electrically coupled between the power and return rails of a power distribution and functions to suppress noise, such as for example higher frequency voltage spikes. This noise suppression occurs because the capacitor provides a low impedance at higher frequencies.

When two or more power distribution arrangements are associated with a circuit board, the power and return plane pairs may have adjacent edges that run parallel with each other. Noise coupling between adjacent power planes therefore can occur and as a result adjacent power planes must be separated by a distance that minimizes such coupling. Such spacing requirements consume space on the circuit board which also makes the board larger and less compact. FIGS. 4A and 4B illustrate in plan and cross-section a circuit board having a known configuration. In this case, the circuit board A may be a single or multilayer board having a surface B on which are mounted circuit components. There are two separate power distributions arrangements C and D for this circuit board. Power distribution C includes a power rail E and a return rail F, while power distribution D includes a power rail G and a return rail H. The board A includes one or more surfaces B on which are one or more mounted circuit components K The circuits K associated with one of the power distributions may be the same or different from the circuits K′ on the other power distribution. Each component group K, K′ receives electrical power from its associated power distribution depending on the circuit design and layout of the circuit board. The power distribution planes may be positioned in one or more layers below or adjacent the surface J, or may be disposed on the surface B. The circuit components make electrical connection to the power and return planes by any number of techniques including conductive circuit lines, vias, plated through holes and so on. With there being two split power and return planes, each power/return pair includes and edge L and M respectively that run parallel for a distance with each other. Each power distribution may also include a suppression capacitor N and P. In order to minimize or eliminate coupling between the power planes C and D, the adjacent edges L and M must be separated by a minimum distance W. This distance W is in the range of about 200 mils or more, this distance being typical for ESD isolation between adjacent power plane edges for example.

### SUMMARY

The invention provides method and structure for modifying the boundary conditions between edges of adjacent or nearby power distribution planes. The modified boundary conditions reduce coupling between the power distribution planes, which reduces noise coupling between the power planes and allows for closer spacing between the power distribution planes. In a circuit board application, for example, this closer spacing of the power distribution planes frees up more useful space on the circuit board or can reduce the size of the circuit board.

In one embodiment, the boundary conditions are modified by providing mismatched impedances. This impedance mismatch prevents or substantially reduces coupling between the adjacent edges, allowing more closely spaced edges than would otherwise be feasible between power distribution planes. For example, in an area where two power plane edges are near or adjacent each other, one edge boundary is provided with a lower impedance and the other edge is provided with a higher impedance. In an exemplary embodiment, the lower impedance is provided by a capacitance coupled between the power and return rails at or near an edge of one of the power distributions.

In another embodiment, a method is provided for modifying the boundary conditions between edges of adjacent or nearby power distribution planes. The method includes modifying the boundary conditions be providing an impedance mismatch in an area where two power distribution plane edges are near or adjacent each other. This impedance mismatch prevents or substantially reduces coupling between the adjacent edges, allowing more closely spaced edges than would otherwise be feasible between power distribution planes.

### BRIEF DESCRIPTION OF THE DRAWINGS

FIG. 1 is a schematic representation of a first embodiment of the invention showing a plan view of a circuit board;

FIG. 2 is a cross-sectional illustration of the embodiment of FIG. 1 taken along line 2-2 in FIG. 1;

FIG. 3 is a plan view of another embodiment of the invention;

FIGS. 4A and 4B illustrate in plan and cross-section a prior art circuit board configuration;

FIG. 5 is a schematic illustration of an embodiment of the invention; and

FIG. 6 is a schematic illustration of a system incorporating the invention.

### DESCRIPTION OF ILLUSTRATED EMBODIMENTS

In accordance with one aspect of the invention, method and structure are provided for modifying the boundary conditions between edges of adjacent or nearby power distribution planes. The modified boundary conditions reduce coupling between the power distribution planes, which reduces noise coupling between the power distribution planes and allows for closer spacing between the power distribution planes. The invention may be used in any circuit layout configuration that has two or more split power distribution arrangements. By ‘split’ power distribution planes is meant that at least two separate power planes or rails are provided, with the split power planes having either an associated split return plane or the two power planes share a common return plane. In other words, split power distribution planes includes split power and return plane pairs or split power planes that share a common or non-split return plane. The invention will find application in many circuit layouts including but not limited to circuit boards, VLSI (Very Large Scale Integration) circuits, integrated circuits and so on, wherein split power distributions are provided.

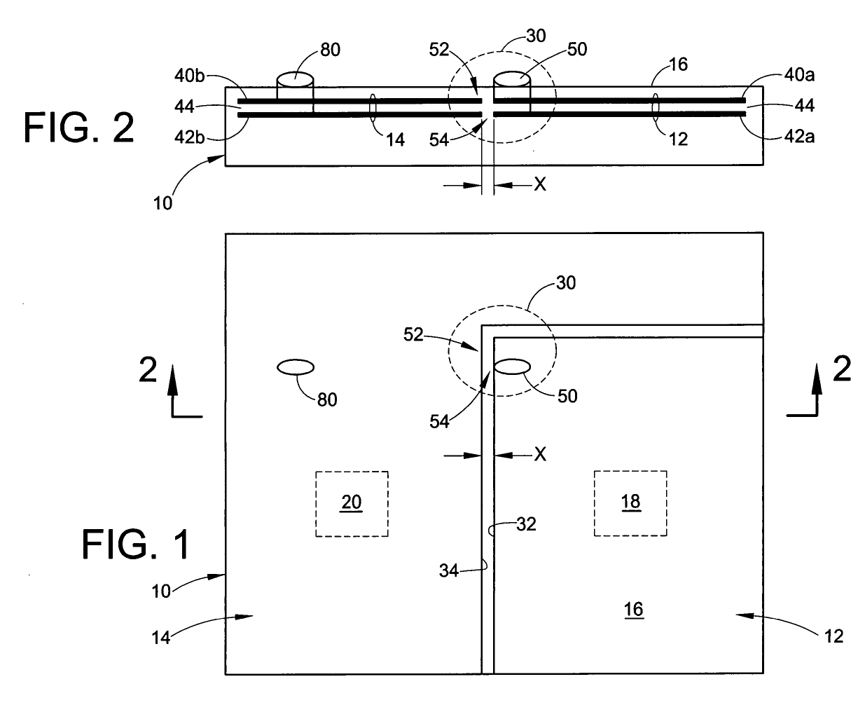

With reference to FIGS. 1 and 2, in a first embodiment a circuit board 10 is illustrated and includes a first power distribution arrangement 12 and a second power distribution arrangement 14. Although the exemplary embodiments herein illustrate the use of two split pairs of power distribution planes, additional power distributions may be provided for specific applications. Each power distribution arrangement in this case is on one or more sub-layers below an outer surface 16 of the circuit board 10. Circuit components 18 associated with the first power distribution 12 may be mounted on the outer surface 16, while circuit components 20 associated with the second power distribution 14 may be mounted on the outer surface 16. Circuit components may be mounted on other surfaces and are electrically connected to the power and return planes by any suitable means or techniques as are well known in the art.

The exemplary configurations that are illustrated with respect to the layout of the circuit components and the specific locations and orientations of the component layouts and power distribution planes geometry are not critical aspects of the invention, but rather are design choices based on the design requirements for the specific circuits and the overall system that the circuit board will be used with. For example, typically circuit components 18 and 20 will be laid out across the entire upper surface 16 of the circuit board 10.

A salient feature of the illustrated layouts is that there is presented a region or area, such as for example the area 30, in which edge portions of the split power distribution planes are near each other or adjacent so as to extend generally parallel with each other over a distance. For example, the first power distribution 12 has an edge portion 32 that runs parallel to an edge portion 34 of the second power distribution 14. These adjacent and parallel edge portions may coextend over a distance or may only be adjacent for a short distance. By ‘adjacent’ or ‘near’ is meant that the edge portions are sufficiently close to each other that undesired coupling could occur between the power distribution planes in the absence of the use of the present invention.

In accordance with one aspect of the invention, the boundary conditions at the adjacent edge portions such as the area 30 are changed so as to minimize or reduce noise coupling between the power distribution planes. Boundary condition refers to the associated impedances at the edges of the split power distribution planes in areas where coupling is to be minimized or reduced. For example, and with reference to FIG. 2, each power distribution arrangement includes a power rail or conductor 40 and a return rail or conductor 42. For clarity, the power and return rails of the first power distribution 12 are designated with the letter ‘a’ and the power and return rails of the second power distribution 14 are designated with the letter ‘b’. The paired power and return rails are separated by an insulated layer 44. These split rail pairs in effect form a high impedance dipole antenna that can support a strong electric field \overline{E} but not a strong magnetic field Ĥ.

Where edges of two separate or split power planes are closely adjacent there can be coupling between the power planes due to dipole coupling between the electric fields supported by the power and return rails. As a result, the adjacent edges must be separated enough to prevent or reduce such coupling, as discussed in the Background above. In the case where suppression capacitors are used with each of the power planes, each capacitor, along with its associated vias and power and return rails, in effect forms a low impedance loop antenna that supports a strong magnetic field (due to current flow) but not a strong electric field. Thus, when two suppression capacitors are used on adjacent edges of split power planes, there must be sufficient spacing between the capacitors again to reduce coupling.

In accordance with one embodiment of the invention, the boundary conditions are changed so as to have a mismatch in impedances at the adjacent edge portions such as for example in the area 30. Mismatched impedances will not couple, or at least the coupling is substantially reduced. By reducing the coupling, the edge portions can be much more closely spaced together, thereby saving substantial space on the circuit layout for other uses or simply reducing the overall dimensions of the circuit layout in some cases.

In the exemplary embodiment of FIGS. 1 and 2, an impedance mismatch in the area 30 is realized in the form of providing a decoupling capacitance 50 along one edge of one of the power planes, while the other power plane still has the dipole type high impedance. This impedance mismatch prevents coupling between the power planes along the adjacent edges because the high impedance side 52 cannot support the magnetic field generated on the low impedance side 54 by current flow through the loop antenna function of the capacitance 50, in effect presenting a high impedance to current. The capacitance 50, or in other words the low impedance side 54 that functions like a loop antenna formed by the capacitance 50 and its associated power and return rail connections, cannot support the electric field of the high impedance side, in effect shorting it out. Thus, in order to decouple adjacent or nearby edges of power distribution planes, one side is provided with a low impedance and the other side is provided with a high impedance. As an example, the decoupling capacitance 50 may be in the form of a capacitor of about a few hundred picofarads to many microfarads. A typical range may be about 1 to about 100 nanofarads but the actual values will be very specific to each circuit layout and design requirements. This decoupling substantially reduces the distance X that must be maintained to prevent coupling.

As an example, by incorporating an impedance mismatch in accordance with the invention, adjacent power plane edges may be spaced a distance X as close as about five to ten mils or less which is substantially more closely spaced than can be achieved without the use of the invention.

Although the embodiment of FIGS. 1 and 2 illustrate split power and return rail pairs for the split power distribution planes, it will be understood by those skilled in the art that the present invention may also be used in configurations in which split power rails are used with a common return rail.

It is important to note that both power distribution arrangements 12, 14 may still utilize suppression capacitances, as is illustrated in FIG. 1. The second power distribution arrangement 14 may for example include a suppression capacitor 80, however, in accordance with the invention this capacitor is disposed sufficiently far from the decoupling capacitance 50 of the other power distribution arrangement 12 so that it cannot couple to that capacitance 50 and also so that the impedance of the second power distribution in the region 30 is a high impedance.

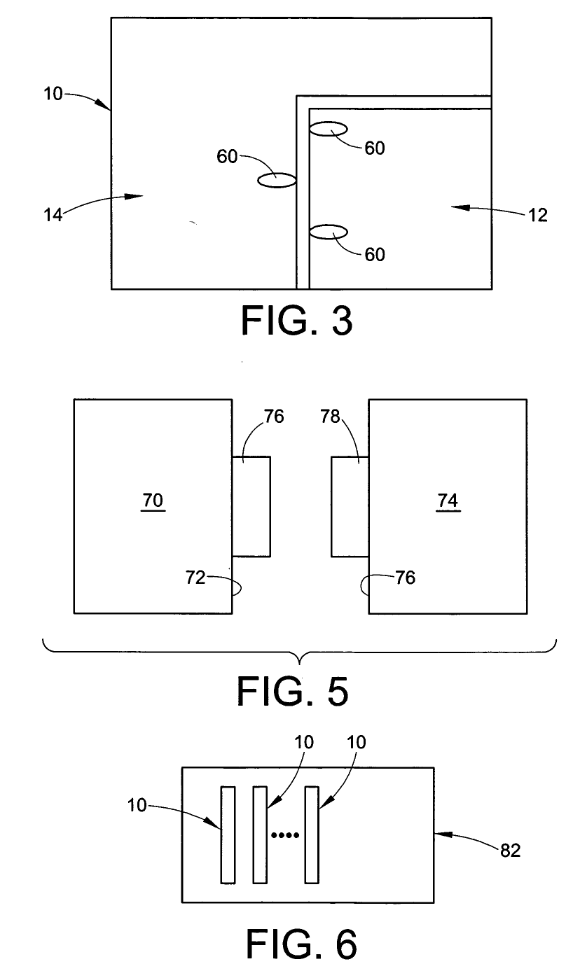

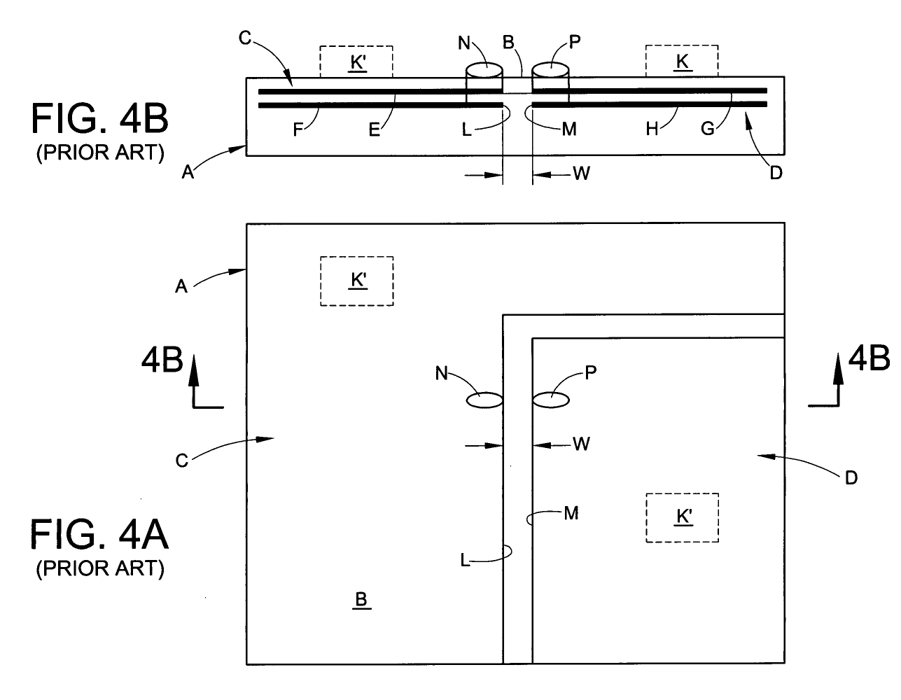

With reference to FIG. 3, in another embodiment of the invention, there may be situations where more than one decoupling capacitance is desired for either or both split power distributions 12 and 14. This may be necessary for example to achieve a desired level of noise suppression or to reduce coupling. For example, this may arise for long runs where the adjacent edges of split power distribution planes coextend for lengthy distances. In accordance with the present invention, the decoupling capacitances 60 should be staggered or otherwise arranged so that each capacitance 60 prevents or reduces coupling with its adjacent high impedance of the adjacent rail edge.

FIG. 5 illustrates the invention in a schematic manner. A first power distribution 70 includes an edge region or portion 72 that is to be spaced near or closely adjacent to a second separate or split power distribution 74 having an edge region or portion 76. The power distributions 70 and 74 may or may not share a common return rail. One of the edge portions is provided with a high impedance 76 that supports an electric field but not a magnetic field and the other edge portion is provided with a low impedance 78 that supports a magnetic field but not an electric field. Note that in FIG. 5 the regions 76 and 78 are intended to only represent functional boundary conditions and not actual physical structure.

FIG. 6 illustrates an exemplary application of the invention. An electronic system 82, such as for example, a computer, has one or more circuit layouts 10 installed therein. The circuit layouts 10 may be for example circuit boards and/or integrated circuits and so on, wherein one or more of said layouts includes two or more split power distributions as set forth herein above.

The invention further contemplates a method for reducing coupling between split power distribution planes thus allowing the split power planes to be more closely spaced that would otherwise be permitted without use of the invention. The method comprises providing a low impedance at the edge portion of one of the power planes and a high impedance at the edge portion of the other power plane. In an exemplary embodiment the low impedance is formed by a decoupling capacitance that in effect forms a low impedance loop antenna when connected to its associated power and return planes. The split power distribution planes may include split power and return rails or split power rails and a common return rail.

While various aspects of the invention are described and illustrated herein as embodied in combination in the exemplary embodiments, these various aspects may be realized in many alternative embodiments, either individually or in various combinations and sub-combinations thereof. Unless expressly excluded herein all such combinations and sun-combinations are intended to be within the scope of the present invention. Still further, while various alternative embodiments as to the various aspects and features of the invention, such as alternative materials, structures, configurations, methods, devices, software, hardware, control logic and so on may be described herein, such descriptions are not intended to be a complete or exhaustive list of available alternative embodiments, whether presently known or later developed. Those skilled in the art may readily adopt one or more of the aspects, concepts or features of the invention into additional embodiments within the scope of the present invention even if such embodiments are not expressly disclosed herein. Additionally, even though some features, concepts or aspects of the invention may be described herein as being a preferred arrangement or method, such description is not intended to suggest that such feature is required or necessary unless expressly so stated. Still further, exemplary or representative values and ranges may be included to assist in understanding the present invention however, such values and ranges are not to be construed in a limiting sense and are intended to be critical values or ranges only if so expressly stated.

The invention has been described with reference to the exemplary and illustrated embodiments. Modifications and alterations will occur to others upon a reading and understanding of this specification and drawings. The invention is intended to include all such modifications and alterations insofar as they come within the scope of the appended claims or the equivalents thereof.

I claim:

1. Circuit layout, comprising:
at least two power distributions wherein a first power distribution includes a first power rail and a first return rail, and a second power distribution includes a second power rail and a second return rail, said first and second power distributions providing power and return for respective and separate circuits, a decoupling capacitance across said power rail and return rail of a first of said two power distributions, said capacitance being disposed at an edge of said first power distribution adjacent said second power distribution, said second power distribution being open circuit impedance between its power rail and return rail along an edge that is adjacent said edge of said first power distribution in an area near said capacitance, wherein said edges are more closely spaced with respect to each other than they would otherwise be spaced without said capacitance and adjacent open circuit impedance area.

2. The circuit layout of claim 1 wherein said open circuit impedance area supports a strong electric field near said capacitance but not a strong magnetic field, and said capacitance supports a strong magnetic field but not a strong electric field, so that said capacitance reduces coupling between said first and second power rails.

3. The circuit layout of claim 1 comprising a second decoupling capacitance across said power rail and return rail of said second power distribution, said second capacitance being disposed sufficiently away from said first capacitance to prevent coupling there between.

4. The circuit layout of claim 1 comprising a third power distribution having a third decoupling capacitance between its power rail and return rail, wherein each said capacitance is at an edge of its respective power distribution and near an open circuit area of an adjacent power distribution.

5. The circuit layout of claim 4 wherein each of said capacitances is disposed sufficiently away from each of the other two capacitances to prevent coupling there between.

6. The circuit layout of claim 1 wherein said first and second return rails are common.

7. A method for closely spacing split power distributions in a circuit, comprising:
decoupling a power rail and return rail of a first power distribution with a short circuit impedance by disposing said short circuit impedance in an edge region of said first power distribution that is adjacent an edge region of a second power distribution, and providing an open circuit impedance between a power rail and return rail of said second power distribution near said short circuit impedance,
wherein said edges are more closely spaced with respect to each other than they would otherwise be spaced without said capacitance and adjacent open circuit area.

8. The method of claim 7 comprising the step of providing a second short circuit impedance to decouple said second power distribution power and return rails, and
spacing said first and second short circuit impedances sufficiently from each other to prevent coupling there between.

9. The method of claim 7 wherein said short circuit impedance comprises capacitance.

10. The method of claim 8 wherein said first and second short circuit impedances comprise capacitance.

11. Circuit layout, comprising:
at least two split power planes wherein a first power plane having a first edge portion and a second power plane has a second edge portion, said first and second edge portions being adjacent and parallel with each other for a distance, said first and second edge portions having different boundary conditions to reduce coupling between said first and second power planes.

12. The circuit layout of claim 11 wherein said boundary conditions comprise an impedance characteristic at each of said edges.

13. The circuit layout of claim 12 wherein said first edge portion has a boundary condition comprising an open circuit impedance and said second edge portion has a boundary condition comprising a short circuit impedance.

14. The circuit layout of claim 13 wherein said open circuit impedance functions like a dipole antenna and said short circuit impedance functions like a loop antenna.

15. The circuit layout of claim 11 wherein said different boundary conditions comprise a substantially open circuit impedance and a substantially short circuit impedance.

16. The circuit layout of claim 15 wherein said short circuit impedance comprises a decoupling capacitance.

17. The circuit layout of claim 15 wherein said open circuit impedance comprises a power rail and a return rail separated from each other by an insulator layer.

18. The circuit layout of claim 17 wherein both said power planes comprise decoupling capacitance that are separated by a distance sufficient to prevent coupling there between.

19. The circuit layout of claim 11 comprising staggered boundary conditions along said distance.

20. The circuit layout of claim 19 wherein said staggered boundary conditions comprise alternating areas of decoupling capacitance and open circuit impedance along said edges.

21. The circuit layout of claim 11 in combination with an electronic system.

22. The circuit layout of claim 21 wherein said circuit layout is laid out on a circuit board and said circuit board is installed in a computer.

23. The circuit layout of claim 11 wherein said circuit layout is disposed on an integrated circuit.
